(19) United States
(12) Patent Application Publication
(10) Pub. No.: US 2007/0164776 A1
(43) Pub. Date: Jul. 19, 2007

(54) DEVICE AND METHOD FOR MEASURING GRAY TO GRAY TRANSITION RESPONSE TIME

(76) Inventors: Pao-Chi Chang, Hsinchu City (TW); Mu-Lin Chao, Taoyuan County (TW); Feng-Chou Ni, Taipei County (TW); Hsin-Mao Huang, Kaohsiung County (TW); Jhih-Hong Jiang, Yilan County (TW)

Correspondence Address: NORTH AMERICA INTELLECTUAL PROPERTY CORPORATION, P.O. BOX 506, MERRIFIELD, VA, 22116, US

(21) Appl. No.: 11/609,342

(22) Filed: Dec. 12, 2006

(30) Foreign Application Priority Data
Jan. 17, 2006 (TW) 095101752

(51) Int. Cl. G01R 31/00

(52) U.S. Cl. 324/770

(57) ABSTRACT

A device for measuring gray-to-gray response times in a display utilizes light detectors to measure the response time of gray images of the display rapidly. The device is used in a measuring system having a temporal signal integrator and a light scope. The temporal signal integrator provides a plurality of signals of gray images for multiple areas on the display, and the light scope includes the light detectors. Each active light detector is distributed to measure the response time of the gray images on each of the areas.

### BACKGROUND OF THE INVENTION

1. Field of the Invention

The present invention relates to measuring response times of a display, and particularly to a device and related method for rapidly measuring a gray-to-gray (GTG) response time of a liquid crystal display (LCD) using a plurality of light detectors.

2. Description of the Prior Art

Because technology related to thin film transistor (TFT) flat panel displays has progressed over time, digital images that are displayed on the displays have developed rapidly as well. With this trend, quick response time for TFT flat panel displays is important. Specifically, the response time has a direct influence on the displayed images, particularly on the quality of performance of dynamic images.

In general, displays are mostly used to browse web pages or to deal with e-documents. In these situations, the image shown on the display often remains constant for a certain period of time before switching to the next image. Fast or slow response time of the display for these steady images does not make a significant difference. However, on the other hand, if the images shown on the display are dynamic images or movies, the displayed image will need to change rapidly without reduction in quality. As a result, the response time of the display is a crucial factor in the quality of the images.

The response time for a liquid crystal display (LCD) depends on a period of time required for the liquid crystal molecules in the panel to rotate and control the gray level of a backlight. As to the specification of the display, the gray level thereof can be divided into 2⁸ different levels, for example. A 0th gray level represents pure dark, while a 255th gray level represents pure white. The other gray levels (1-254) represent intermediary gray levels.

With regards to the 305-1 standard regulated by the Video Electronics Standards Association (VESA), the response time for the gray levels of gray images is measured by first choosing two different gray levels, namely a gray level A and a gray level B. Then, a rise time Tr is measured as brightness changes from 10% to 90% from the gray level A to the gray level B and also measured as a fall time Tf for the brightness as it changes from 90% to 10% from the gray level B to the gray level A. The response time for these two levels is the sum of the rise time and the fall time (T=Tr+Tf).

Typically, the definition for measuring the response time entails the cycle time needed to measure the transition from pure dark to pure white and from pure white to pure dark as shown on the display. However, the cycle time is usually not the longest and there could be no problems during the transitions between pure dark and pure white. The problem lies in the transition from one gray level to another gray level. The response time from one gray level to another gray level of gray images may be many times longer than the response time from pure dark to pure white or pure white to pure dark. For this reason, when a dynamic sequence of images, such as in a movie clip or a video game, is displayed, the images may appear blurry or exhibit artifacts if the transition from one image to the next in the sequence is not sufficiently rapid. This degrades image quality for dynamic pictures.

According to the above, the response time for gray images can be an important index used to evaluate the quality of a liquid crystal display. Traditionally, a photomultiplier tube (PMT) is utilized as a detector to measure the response time for gray-to-gray image transitions. Due to the 256 gray levels of the gray images in a liquid crystal display, the response time needed to measure the change from one gray level to another gray level of these 256 scales, such as transitioning from the 52nd gray level to the 91st gray level, constitutes a gray measurement matrix of 256 by 256. That is, there are 65,536 elements which represent the respective response times for gray-to-gray image transitions, as shown in FIG. 1. FIG. 1 illustrates a gray measurement matrix of 256 by 256, wherein each element Tm_n (m: 0˜256, n: 0˜256) represents the response time for transitioning from an mth gray level to an nth gray level. For example, T₁_{_{—}}₀ indicates the response time required for transitioning from the first gray level to the 0th gray level.

Therefore, it will take a long time to sufficiently measure the response time by using traditional technology to evaluate the quality of liquid crystal displays. Several days are probably needed to finish all response time measurements and calculations for the gray images. In practice, it is not only a heavy load for the display manufacturer to proceed with the quality control of the displays, but also an inconvenience for the buyer to test or inspect the displays while purchasing.

It is a key issue to measure the response time for all gray images of a liquid crystal display quickly, efficiently, and precisely. Therefore, it is essential to create a new device, a system and a method for measuring the gray-to-gray response time of a liquid crystal display to promote the quality thereof.

### SUMMARY OF THE INVENTION

According to the present invention, a light scope for measuring a gray-to-gray response time of a display comprises a plurality of light detectors. Each of the active light detectors is configured to measure one of a plurality of gray measurement matrices of a gray measurement matrix. Each element of the gray measurement matrix represents a response time of the display transitioning from an initial gray level to a target gray level.

According to the present invention, a light scope for measuring a gray-to-gray response time of a display comprises a plurality of light detectors. Each of the active light detectors cooperates to measure a response time of transitioning gray images on a plurality of areas of the display. The number of the active light detectors and the number of the areas are the same, and the response time of transitioning each of the gray images is the time of the display transitioning from an initial gray level to a target gray level.

According to the present invention, a method of measuring a gray-to-gray response time of a display comprises locating a plurality of active light detectors corresponding to a plurality of areas of the display, initiating a plurality of gray images in the plurality of areas of the display, and utilizing the active light detectors to measure the response time when transitioning the gray images in the plurality of areas of the display.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a gray measurement matrix of the prior art.

FIG. 2 illustrates an embodiment of the present invention.

FIG. 3 illustrates a gray measurement matrix divided into a plurality of gray measurement matrices in an embodiment of the present invention.

FIG. 4 illustrates a flow chart of the measuring method of the present invention.

FIG. 5 illustrates the initiated gray images.

FIG. 6 illustrates the sequences of initiating the gray images.

### DETAILED DESCRIPTION

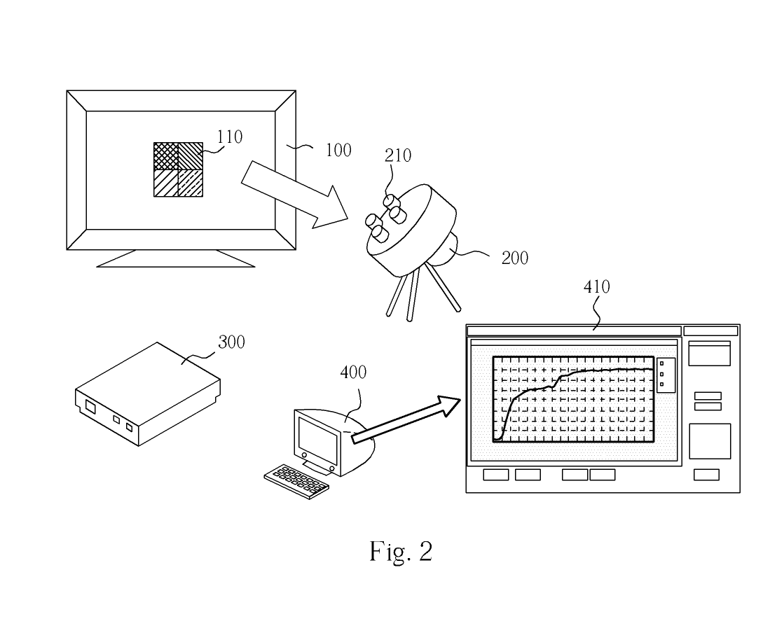

FIG. 2 illustrates a preferred embodiment of the present invention. A system which utilizes a plurality of detectors for rapidly measuring the gray-to-gray (GTG) response time of transitioning gray images of a display is disclosed. The system comprises a light scope 200, a temporal signal integrator 300 and a terminal control device 400 for measuring the GTG response time of the gray images transitioning in the display 100. The display 100, for example, can be a liquid crystal display (LCD) and can be configured to a suitable place with a light scope 200. Moreover, the light scope 200 connects to the temporal signal integrator 300, while the temporal signal integrator 300 connects to the display 100 and the terminal control device 400, respectively.

It is noted that the present invention is different from the prior art in that the light scope 200, which comprises a plurality of light detectors 210, can coordinate to measure the response time for all gray image transitions simultaneously to reduce the measuring time of the prior art sufficiently. A detailed description is disclosed below.

The light scope 200 disclosed by the invention comprises a plurality of light detectors 210 to measure the GTG response time for all gray image transitions in the display. Specifically, the exposure time or the gain value of the active light detector of the light scope of the present invention can be adjusted so that the light scope can be adapted to displays with different brightness. For example, both a brighter panel utilized in a digital television and a dimmer panel utilized in a mobile phone can use the light scope of the present invention to measure the GTG response time thereof. The active light detector 210 is selected from a group comprised of the following: photodiode (PD), PIN photodiode, avalanche photodiode (APD), a charge coupled device (CCD), complementary metal-oxide semiconductor (CMOS), or a combination thereof. The temporal signal integrator 300 can choose a zone, corresponding with the active light detectors 210, on a display 100 and divide the zone into a plurality of areas 110 having a number corresponding to the number of the active light detectors. The temporal signal integrator 300 also provides a plurality of gray images to those areas 110 on the display 100 for measurement by the active light detectors 210.

Specifically, in a preferred embodiment of the present invention, the light detectors 210 are configured into an array in the light scope 200, as shown in FIG. 2. The light scope 200 comprises, for example, four light detectors 210 arranged in a 2-by-2 light detector matrix. Moreover, the areas are arranged to form an area array so that the gray images shown in the area array will be arranged in a pattern matrix 110 shown on the display 100 by the temporal signal integrator 300. The pattern matrix 110 corresponds with the positions of the four light detectors 210 of the light detector matrix. Accordingly, the four light detectors coordinate to measure the GTG response time of transitions of all gray images simultaneously.

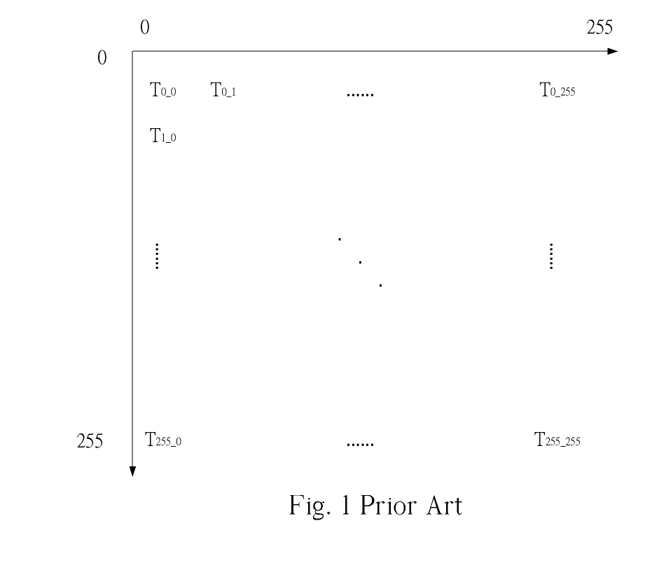

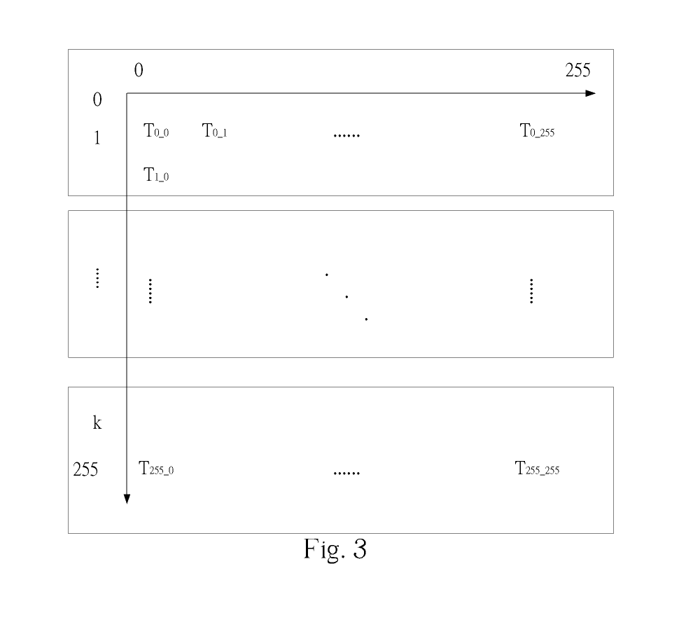

Furthermore, according to the disclosure of the present invention, FIG. 3 illustrates the gray measurement matrix, as shown in FIG. 1, divided into a plurality of gray measurement matrices according to the number of the active light detectors 210 utilized by the light scope 200. In FIG. 3, it is assumed that the light scope 200 comprises k active light detectors. Therefore, it is necessary to divide the gray measurement matrix into k gray measurement matrices, wherein the calculation of the first gray measurement matrix is assigned to the first active light detector, the calculation of the second gray measurement matrix is assigned to the second active light detector, and so forth. It is noted that, similar to the prior art, each element in the gray measurement matrix or in the gray measurement matrix represents the GTG response time needed for measuring the time for transitioning from an initial gray level to the target gray level.

Compared with the prior art, which uses a single PMT as the light detector, the light scope disclosed by the present invention can sufficiently reduce the measuring time. The light scope of the present invention reduces time by utilizing the plurality of light detectors that coordinate with the temporal signal integrator, to simultaneously share the work of measuring the response time of different gray images shown on the corresponding areas of the display. Therefore, the disadvantage of the prior art technology can be eliminated.

It is also noted that the present invention adds a reset process in the transition to the next gray image to enhance the measurement precision of the active light detector, and thereby, result in fast and precise measurement time. The reset step is performed before transition to the next gray image. That is, before transitioning the initial gray level to the target gray level, the temporal signal integrator performs a reset gray level to the corresponding areas for each active light detector so that the active light detector can detect the levels. Thus, the active light detector can be reset to enhance the precision of the active light detector for measuring the GTG response time of the gray images.

Next, with reference to FIG. 2, the temporal signal integrator 300 can further capture the electric signals generated by the active light detectors 210 of the light scope 200 and process the signals. Thereafter, the temporal signal integrator 300 transmits a processed signal, generated after signal processing, to the terminal control device 400. The terminal control device 400 can, for example, be a computer. An image analysis software 410 saved in the terminal control device 400 further calculates the response time of transitioning the gray images according to the processed signal. The detailed descriptions about signal processing and calculations are not relevant with the present invention, so they are omitted.

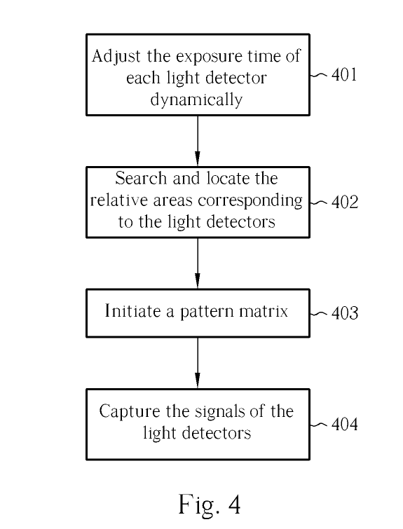

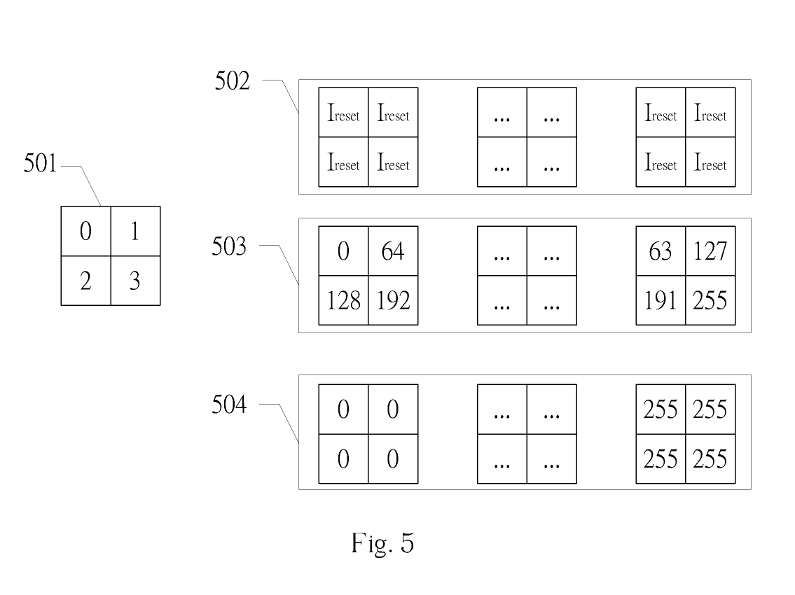

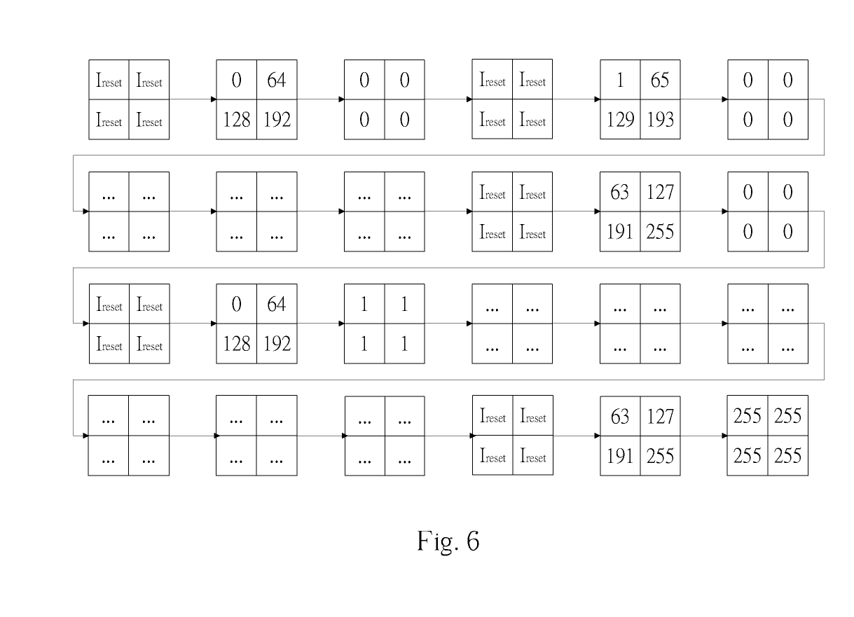

An example of a light scope comprising four light detectors will be disclosed below to explain a method for measuring the response time of a display by this invention. Please refer to FIG. 4, FIG. 5 and FIG. 6 together, wherein FIG. 4 is a flow chart illustrating the measuring method, and FIG. 5 and FIG. 6 illustrate how these four light detectors share the work of measuring the response time.

First, in Step 401, the exposure time and the gain value of each active light detector of the light scope are dynamically adjusted to facilitate the following measurement.

Next, in Step 402, a configuration relationship is established between the display and the light scope. That is, the active light detectors of the light scope search and locate corresponding to the relative areas on the display. In further detail, the first step involves a search for a plurality of approximate vertical positions of the active light detectors on the display by using a wider horizontal scan bar that sequentially scans the display in a vertical direction. According to the light intensity scanned by the light scope, a plurality of approximate vertical positions relative to the active light detectors on the display can be rapidly obtained. The second step involves a search for the relative precise positions for each active light detector on the display within the scope of those approximate vertical positions. That is, a thinner horizontal scan bar sequentially scans the display in a vertical direction within that scope and a plurality of precise vertical positions relative to the active light detectors on the display can be obtained according to the light intensity scanned by the light scope.

The third step involves a search for the plurality of approximate horizontal positions of the active light detectors on the display by using a wider vertical scan bar that sequentially scans the display in a horizontal direction. According to the light intensity scanned by the light scope, a plurality of approximate horizontal positions relative to the active light detectors on the display can be rapidly obtained.

The fourth step involves the search for relative precise positions for each active light detector on the display within the scope of those approximate horizontal positions. That is, a thinner vertical scan bar sequentially scans the display in a horizontal direction within that scope. A plurality of those precise horizontal positions relative to the active light detectors on the display can be obtained according to the light intensity scanned by the light scope.

In step 403, the transition of the plurality of gray images on the relative areas of the display is initiated. In FIG. 5, four active light detectors are used in the light scope of the embodiment and the detectors are arranged in a small 2-by-2 matrix so that the detectors 501 are numbered 0, 1, 2, 3 respectively, as shown in the drawing. Similarly, after the temporal signal integrator obtains the relative positions of the four active light detectors according to the locating process described above, a 2-by-2 pattern matrix corresponding to the relative positions of the four active light detectors is properly arranged on the display. In more detail, the method of the present invention for initiating the pattern matrix is to divide the gray measurement matrix into four gray measurement matrices, wherein the active light detector with the number 0 is assigned to calculate the GTG response times from T₀_{_{—}}₀˜T₆₃_{_{—}}₂₅₅; the active light detector with the number 1 is assigned to calculate the GTG response times from T₆₄_{_{—}}₀˜T₁₂₇_{_{—}}₂₅₅; the active light detector with the number 2 is assigned to calculate the GTG response times from T₁₂₈_{_{—}}₀˜T₁₉₁_{_{—}}₂₅₅; and the active light detector with the number 3 is assigned to calculate the GTG response times from T₁₉₂_{_{—}}₀˜T₂₅₅_{_{—}}₂₅₅. Please note that the present invention is not limited to configurations with 256 gray levels. The use of 256 gray levels in this description is only for example.

Accordingly, the temporal signal integrator divides all of the gray images into three portions shown in the 2-by-2 pattern matrix. The three portions include a reset frame 502, an initial frame 503, and a target frame 504 respectively, wherein the frames 502, 503, and 504 sequentially initiate the 2-by-2 pattern matrix in rotations. The number shown in each frame represents a different gray level. For example, the reset frame 502 is used to reset the gray level in each area so that it includes 64 pattern matrices which all consist of the matrix (Iᵣₑₛₑₜ, Iᵣₑₛₑₜ, Iᵣₑₛₑₜ, Iᵣₑₛₑₜ). The 64 pattern matrices shown in the initial frame 503 are (0, 64, 128, 192), (1, 65, 129, 193) . . . (63, 127, 191, 255), respectively. The 64 pattern matrices shown in the target frame 504 are (Iᵣₑₛₑₜ, Iᵣₑₛₑₜ, Iᵣₑₛₑₜ, Iᵣₑₛₑₜ), (1, 1, 1, 1) . . . (255, 255, 255, 255) respectively.

Based on the description above, FIG. 6 illustrates the sequence of the gray image which is initiated by the temporal signal integrator and shown in the 2-by-2 pattern matrix of the areas on the display, wherein a complete transition of gray images consists of all three frames. For example, the pattern matrix (Iᵣₑₛₑₜ, Iᵣₑₛₑₜ, Iᵣₑₛₑₜ, Iᵣₑₛₑₜ) is used to reset, and then, the initial gray images of the pattern matrix (0, 64, 128, 192) are initiated respectively on the relative areas of the display corresponding to the active light detectors of number 0, 1, 2, 3. Later, the target gray images of the pattern matrix (0, 0, 0, 0) are initiated respectively. With the last group of pattern matrices (Iᵣₑₛₑₜ, Iᵣₑₛₑₜ, Iᵣₑₛₑₜ, Iᵣₑₛₑₜ), (63, 127, 191, 255), (255, 255, 255, 255) initiated, all gray images of the pattern matrix have been initiated.

In step 404, the active light detectors coordinate to measure the GTG response times for transitioning the gray images in the relative areas. It is noted that the active light detectors measure simultaneously with the execution of step 403. After the temporal signal integrator initiates all the elements of the pattern matrix, the active light detectors start measuring all the response times signals generated accordingly and the signals are also captured and processed by the temporal signal integrator. The detailed description of this process is similar to that mentioned above.

To sum up, the present invention uses a plurality of light detectors that coordinates with the configuration of the pattern matrix of gray images to share the measurement of the response time of a display. Not only is the present invention fast, but it also efficiently measures the response time of the liquid crystal display using the technology disclosed by the invention to evaluate the performance of showing dynamic images therein. It is essentially helpful for the design of a display during the stage of development.

The above disclosure is related to the detailed technical contents and inventive features thereof. People skilled in this field may proceed with a variety of modifications and replacements based on the disclosures and suggestions of the invention as described without departing from the characteristics thereof. For example, the configuration of the active light detectors of the light scope and the pattern matrix of the display may be modified according to the real application. Nevertheless, although such modifications and replacements are not fully disclosed in the above descriptions, they have substantially been covered in the following claims as appended.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A light scope for measuring a gray-to-gray response time of a display, the light scope comprising:
a plurality of light detectors, each active light detector being configured to measure one of a plurality of gray measurement matrices of a gray measurement matrix;
wherein each element of the gray measurement matrix represents a response time of the display transitioning from an initial gray level to a target gray level.

2. The light scope of claim 1, wherein both the initial gray level and the target gray level comprise N gray images and the gray measurement matrix is an N×N matrix.

3. The light scope of claim 1, wherein the active light detectors adjust an exposure time or a gain value corresponding to a brightness of the display.

4. The light scope of claim 1, wherein the light detectors are arranged to form a light detector array to measure a pattern matrix on a relative zone of the display.

5. A light scope for measuring a gray-to-gray response time of a display, the light scope comprising:
a plurality of light detectors, each active light detector cooperating to measure a response time of transitioning gray images on a plurality of areas of the display;
wherein the number of the active light detectors and the number of the areas are the same, and the response time of transitioning each of the gray images is the time of the display transitioning from an initial gray level to a target gray level.

6. The light scope of claim 5, wherein both the initial gray level and the target gray level comprise N gray images.

7. The light scope of claim 5, wherein the active light detectors adjust an exposure time or a gain value corresponding to a brightness of the display.

8. The light scope of claim 5, wherein the light detectors are arranged to form a light detector array and the areas are arranged to form a corresponding area array to show the gray images.

9. A method of measuring a gray-to-gray response time of a display, the method comprising:
locating a plurality of active light detectors corresponding to a plurality of areas of the display;
initiating a plurality of gray images in the plurality of areas of the display; and
utilizing the active light detectors to measure the response time when transitioning the gray images in the plurality of areas of the display.

10. The method of claim 9 further comprising a step of adjusting an exposure time or a gain value of the active light detector corresponding to a brightness of the display.

11. The method of claim 9, wherein the step of locating the active light detectors corresponding to the plurality of areas of the display comprises:
searching a plurality of approximate vertical positions of the active light detectors on the display;
searching a plurality of precise vertical positions for each of the active light detectors on the display within a scope of the approximate vertical positions;
searching a plurality of approximate horizontal positions of the active light detectors on the display; and
searching a plurality of precise horizontal positions for each of the active light detectors on the display within a scope of the approximate horizontal positions.

12. The method of claim 9 further comprising a step of arranging the light detectors to form a light detector array and arranging the plurality of areas to form a corresponding area array to show the gray images.

13. The method of claim 12 further comprising utilizing a temporal signal integrator to initiate a plurality of signals corresponding to the gray images transitioning in the area array.

14. The method of claim 9, wherein the response time of transitioning each of the gray images is a time for the display to transition from an initial gray level to a target gray level.

15. The method of claim 14 further comprising a step of resetting before the step of transitioning from the initial gray level to the target gray level, wherein the step of resetting comprises displaying a reset gray level in the relative areas for the active light detectors.

16. The method of claim 14, wherein both the initial gray level and the target gray level comprise M gray images, wherein m is a positive integer.

17. The method of claim 9 further comprising a step of providing a signal to a temporal signal integrator to process the signal from the light scope.

18. The method of claim 17, further comprising a step of sending a processed signal to software to calculate the response time of transitioning the gray images after the temporal signal integrator processes the signal.
